(19) United States
(12) Patent Application Publication
(10) Pub. No.: US 2024/0120208 A1
(43) Pub. Date: Apr. 11, 2024

(54) METHOD FOR FABRICATING SPACER

(71) Applicant: UNITED MICROELECTRONICS CORP., Hsinchu (TW)

(72) Inventor: ZIHAO HUA, Singapore (SG)

(21) Appl. No.: 17/983,426

(22) Filed: Nov. 9, 2022

(30) Foreign Application Priority Data
Oct. 10, 2022 (CN) 202211233885.0

(51) Int. Cl. H01L 21/311

(52) U.S. Cl. CPC H01L 21/31116

(57) ABSTRACT

A method for fabricating a spacer includes steps as follows: Firstly, an etch stop structure is provided. The etch stop structure includes a silicon nitride-containing capping layer covering a substrate. Next, an etching process is performed to remove a portion of the silicon nitride-containing capping layer. A wet process is then performed making a sulfide-containing treatment agent to contact the remaining portion of the silicon nitride-containing capping layer.

This application claims the benefit of People's Republic of China application Serial No. 202211233885.0 filed Oct. 10, 2022, the subject matter of which is incorporated herein by reference.

### BACKGROUND

### Technical Field

The disclosure relates to a method for fabricating a semiconductor device, and more particularly to a method for forming an insulating spacer structure in a semiconductor process.

### Description of Background

Insulating spacer structures are widely used in the fabrication of integrated circuits, which are mainly used as insulating structures for separating two conductive patterns (or elements) or serving as shielding elements in a semiconductor process (e.g., an ion implantation process or an etching process). For example, in the process of fabricating a metal-oxide-semiconductor-field-effect-transistor (MOSFET) with a lightly-doped-drain (LDD) and/or a source, spacers can be disposed on the sidewall of the polysilicon gate to isolate the gate from the drain/source, and can be used as shielding elements for the ion implantation process of forming the drain/source region.

Through the shielding (alignment) of these spacers, the intrinsic size of the device can be indirectly defined, which is a very critical step in the manufacturing process of the integrated circuit and has a great influence on the characteristics of the device. As the device critical dimension shrinks, the (width) dimensions of these spacers must be precisely defined in a very controllable and repeatable manner in order to satisfy the stringent requirements of yield and reliability.

Currently, advanced process control (APC) and/or advanced equipment control (AEC) technology have been adopted by the prior art, collecting a huge amount of process data and/or applying a large number of mathematical and statistical methods to reduce process variation, etc. to improve the efficiency of equipment operation and increase the yield and reliability (for fabricating spacers).

However, the APC and/or AEC technology usually have to be seamlessly supported by multiple engineering systems, such as a Run-to-Run (R2R) batch control system, a fault detection and classification (FDC) system, an overall equipment efficiency (OEE) system, and an online automatic diagnosis system, etc., which are costly. Therefore, how to precisely control the (width) size of the spacers with simplified manufacturing procedures and lower manufacturing costs is still one of the important issues for those skilled in the art.

Therefore, there is a need of providing an advanced method for fabricating a spacer to obviate the drawbacks encountered from the prior art.

### SUMMARY

One aspect of the present disclosure is to provide a method for fabricating a spacer, wherein the method includes steps as follows: Firstly, an etch stop structure is provided. The etch stop structure includes a silicon nitride-containing capping layer covering a substrate. Next, an etching process is performed to remove a portion of the silicon nitride-containing capping layer. A wet process is then performed making a sulfide-containing treatment agent to contact the remaining portion of the silicon nitride-containing capping layer.

In accordance with the aforementioned embodiments of the present disclosure, a method for fabricating a spacer is provided. An etch stop structure including a silicon nitride-containing capping layer covering on a semiconductor substrate is formed. A portion of the etch stop structure is firstly removed by at least one etching process to define the profile of the spacer, and then a wet process is performed using a sulfide-containing treatment agent to contact the remaining portion of the silicon nitride-containing capping layer. Such that the remaining portion of the silicon nitride-containing capping layer in the spacers can be partially removed by sulfuric acid in the wet process, and the dimension of the remaining portion of the silicon nitride-containing capping layer can be adjusted according to the function relationship between the sulfuric acid removal rate and the width of the remaining portion of the silicon nitride-containing capping layer (e.g., the etching rate of the sulfide-containing treatment agent against the remaining portion of the silicon nitride-containing capping layer can be further controlled by reducing/increasing the concentration of sulfide in the sulfide-containing treatment agent). By this approach, the invention objective of precisely controlling the (width) dimension of the spacer can be therefore achieved through a simpler manufacturing procedure and a lower manufacturing cost.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1 is a processing flowchart illustrating a method for fabricating a spacer, in accordance with one embodiment of the present disclosure; and

FIGS. 2A-2D are cross-sectional views illustrating a series of process structures for forming a spacer, in accordance with one embodiment of the present disclosure.

### DETAILED DESCRIPTION

The embodiments as illustrated below provide a method for fabricating a spacer to achieve the invention objective of precisely controlling the (width) dimension of the spacer. The present disclosure will now be described more specifically with reference to the following embodiments illustrating the structure and arrangements thereof.

It is to be noted that the following descriptions of preferred embodiments of this disclosure are presented herein for purpose of illustration and description only. It is not intended to be exhaustive or to be limited to the precise form disclosed. Also, it is important to point out that there may be other features, elements, steps, and parameters for implementing the embodiments of the present disclosure which are not specifically illustrated. Thus, the descriptions and the drawings are to be regarded as illustrative rather than restrictive. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

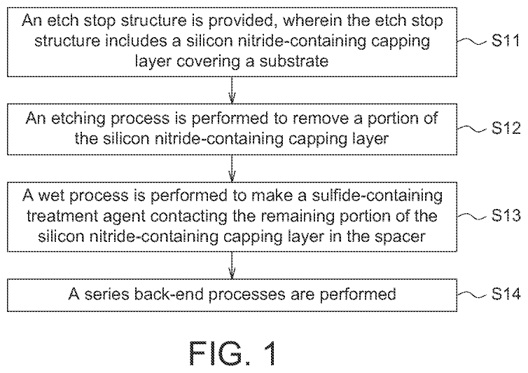

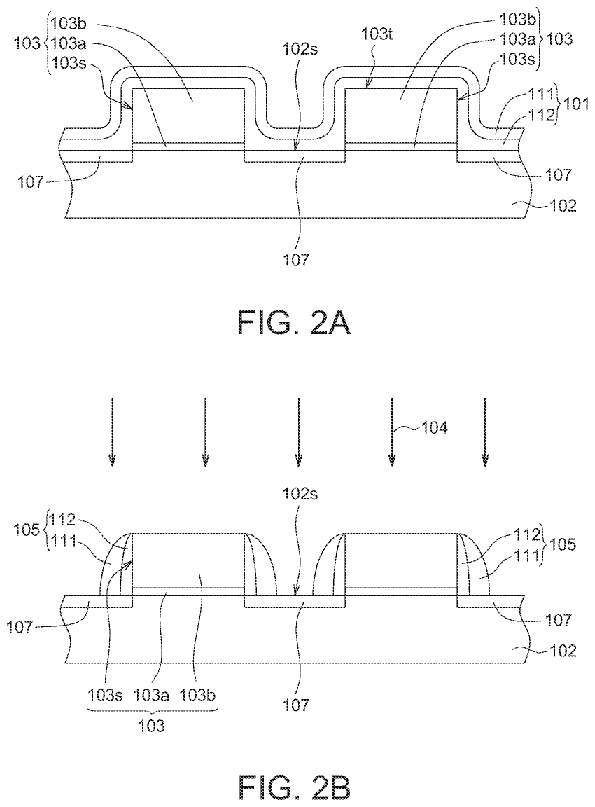

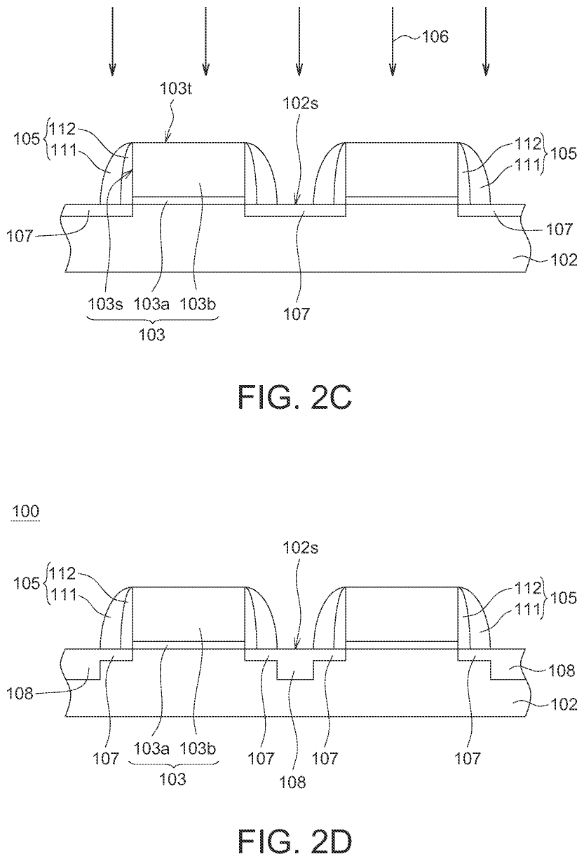

FIG. 1 is a processing flowchart illustrating a method for fabricating a spacer 105, in accordance with one embodiment of the present disclosure. FIGS. 2A-2D are cross-sectional views illustrating a series of process structures for forming the spacer 105, in accordance with one embodiment of the present disclosure. In some embodiments of the present disclosure, the spacer 105 may serve as an insulating structure covering sidewalls 103s of a gate structure 103 of a metal-oxide-semiconductor (MOS) transistor 100. However, the application of the spacer 105 is not limited thereto.

The method for forming the spacers 105 includes steps as follows: Firstly, as illustrated in step S11, an etch stop structure 101 is provided, wherein the etch stop structure 101 includes a silicon nitride-containing capping layer 111 covering a substrate 102. In some embodiments of the present disclosure, the substrate 102 may be a semiconductor substrate.

In some other embodiments of the present disclosure, in addition to a semiconductor base layer, the substrate 102 further includes other semiconductor layers, such as an epitaxial layer or an insulating layer. For example, in one specific embodiment of the present disclosure, the substrate 102 may be a silicon-on-insulator (SOI) substrate including an insulating layer. In the present embodiment, the substrate 102 may be a silicon wafer (regarded to as a semiconductor layer).

In addition, the substrate 102 may further include a plurality of semiconductor devices formed by a front-end process. For example, in the present embodiment, the substrate 102 further includes a gate structure 103 formed on a surface 102s of the silicon wafer (the semiconductor layer); and the etching stopper structure 101 covers a top surface 103t and sidewalls 103s of the gate structure 103.

In the present embodiment, the gate structure 103 includes a gate dielectric layer 103a disposed on the surface 102s of the silicon wafer (semiconductor layer) and a gate electrode layer 103b disposed on the gate dielectric layer 103a. The gate structure 103 can serve as a mask during a plurality of implantation processes, for forming a plurality of lightly doped drains (LDD) 107 in different well regions (not shown) of the silicon wafer (semiconductor layer) respectively (as shown in FIG. 2A).

In some embodiments of the present disclosure, the etch stop structure 101 can be formed on the surface 102s of the silicon wafer (semiconductor layer) and covering the gate structure 103 by a deposition process, such as a chemical vapor deposition (CVD) or a flow chemical vapor deposition. A portion of the etch stop structure 101 may fill in the openings (not shown) formed on the surface 102s of the silicon wafer (semiconductor layer), thereby forming a shallow trench isolation (STI) (not shown).

In addition, the etch stop structure 101 may be a multi-layer structure. For example, in some embodiments of the present disclosure, in addition to the silicon nitride-containing capping layer 111, the etch stop structure 101 further includes a silicon oxide layer 112 disposed between the substrate 102 and the silicon nitride-containing capping layer 111. The silicon oxide layer 112 covers the top surface 103t and the sidewalls 103s of the gate structure 103; and the silicon nitride-containing cover layer 111 covers the silicon oxide layer 112. The silicon nitride-containing capping layer 111 may include silicon nitride (Si₃N₄); the silicon oxide layer 112 may include silicon dioxide (SiO₂).

However, the multi-layer structure constituting the etch stop structure 101 is not limited to this regard. Any multi-layer structure in which using the silicon nitride-containing capping layer 111 as the outermost layer (or the uppermost layer) and serving as an etch stop layer does not depart from the technical scope of the etch stop structure 101 of the present invention.

Next, as illustrated in step S12, an etching process 104 is performed to remove a portion of the silicon nitride-containing capping layer 111. In some embodiments of the present disclosure, the etching process 104 may be an anisotropic etching process, such as a dry etching process, or a reactive ion etching (RIE) process, to remove portions of the silicon nitride-containing capping layer 111 and the silicon oxide layer 112 in the etch stop structure 101, and to leave portions of the silicon nitride-containing capping layer 111 and the silicon oxide layer 112 on the sidewalls (the vertical walls) 103s of the gate structure 103 (as shown in FIG. 2B). In the present embodiment, the portions of the silicon nitride-containing capping layer 111 and the silicon oxide layer 112 remaining on the sidewalls (the vertical walls) 103s of the gate structure 103 can be used as the spacers 105 of the gate structure 103.

After that, as illustrated in step S13, a wet process 106 is performed to make a sulfide-containing treatment agent contacting the remaining portion of the silicon nitride-containing capping layer 111 in the spacer 105. In some embodiments of the present disclosure, the sulfide-containing treatment agent in the wet process 106 include sulfuric acid (H₂SO₄), hydrogen peroxide (H₂O₂) and water. The concentration of sulfuric acid in the sulfide-containing treatment agent is substantially between 50 wt % and 95 wt %. For example, in the present embodiment, the sulfide-containing treatment agent can be a SPM solution; and the sulfuric acid concentration in the mixed acid solution of sulfuric acid and hydrogen peroxide is substantially between 81 wt % and 66 wt %. In some embodiments of the present disclosure, the sulfide-containing treatment agent in the wet process 106 includes H₂SO₄, caro's acid (H₂SO₅) or the combination thereof.

The sulfuric acid in the sulfide-containing treatment agent can not only remove the impurity particles located on the surface of the spacer 105 but also act on the silicon nitride in the silicon nitride-containing capping layer 111 of the spacer 105:

Si₃N₄+4H₂SO₄+10H₂O→Si₃O₂(OH)₈+4NH₄HSO₄

Accordingly, the sulfuric acid can further (partially) remove a portion of the silicon nitride-containing capping layer 111 that are remained after the etching process 104.

In some embodiments of the present disclosure, the width of the remaining portion of the silicon nitride-containing capping layer 111 in the spacer 105 is a function of the sulfuric acid concentration. By calculating the functional relationship between the sulfuric acid concentration in the sulfide-containing treatment agent and the width of the remaining portion of the silicon nitride-containing capping layer 111 in the spacer 105, the dimension of the remaining portion of the silicon nitride-containing capping layer 111 in the spacer 105 can be further adjusted, so as to fine-tune the width of the spacer 105.

For example, in the present embodiment, the sulfuric acid concentration in the sulfide-containing treatment agent is in the range of 81 wt % to 66 wt %, and the removal rate of the sulfuric acid against the remaining portion of the silicon nitride-containing capping layer 111 in the spacer 105 exhibits an inverse linear relationship. Therefore, during the wet treatment 106, by monitoring the change of the sulfuric acid concentration in the sulfide-containing treatment agent, the width of the remaining portion of the silicon nitride-containing capping layer 111 can be accurately estimated after the wet treatment 106, so as to fine-tune the width of the spacer 105. In some embodiments of the present disclosure, the removal rate of sulfuric acid against the remaining portion of the silicon nitride-containing capping layer 111 in the spacer 105 can also be estimated by calculating the process time of the wet treatment 106, so as to calculate the width of the remaining portion of the silicon nitride-containing capping layer 111 after the wet treatment 106.

In some embodiments of the present disclosure, the functional relationship between the width of the remaining portion of the silicon nitride-containing capping layer 111 in the spacer 105 and the concentration of sulfuric acid in the sulfide-containing treatment agent can also be taken account by the APC system and/or the AEC system used to fabricate the MOS transistor 100, in order to fine-tune and control the width of the spacer 105 more precisely.

Subsequent, as illustrated in step S14, a series back-end processes are performed (such as, forming a plurality of source/drain structures 108 in the substrate 102, and forming a metal interconnection structure (not shown) to electrically connect with the gate electrode layer 103b of the gate structure 103 and the source/drain structures 108), so as complete the preparation of the MOS transistor 100 as shown in FIG. 2D.

In accordance with the aforementioned embodiments of the present disclosure, a method for fabricating a spacer is provided. An etch stop structure including a silicon nitride-containing capping layer covering on a semiconductor substrate is formed. A portion of the etch stop structure is firstly removed by at least one etching process to define the profile of the spacer, and then a wet process is performed using a sulfide-containing treatment agent to contact the remaining portion of the silicon nitride-containing capping layer. Such that, the remaining portion of the silicon nitride-containing capping layer in the spacers can be partially removed by sulfuric acid in the wet process, and the dimension of the remaining portion of the silicon nitride-containing capping layer can be adjusted according to the function relationship between the sulfuric acid removal rate and the width of the remaining portion of the silicon nitride-containing capping layer (e.g., the etching rate of the sulfide-containing treatment agent against the remaining portion of the silicon nitride-containing capping layer can be further controlled by reducing/increasing the concentration of sulfide in the sulfide-containing treatment agent). By this approach, the invention objective of precisely controlling the (width) dimension of the spacer can be therefore achieved through a simpler manufacturing procedure and a lower manufacturing cost.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for fabricating a spacer, comprising:
providing an etch stop structure that comprises a silicon nitride-containing capping layer covering a substrate;
performing an etching process to remove a portion of the silicon nitride-containing capping layer; and
performing a wet process to make a sulfide-containing treatment agent contacting a remaining portion of the silicon nitride-containing capping layer.

2. The method according to claim 1, wherein the etching process comprises a dry etching process.

3. The method according to claim 1, wherein the substrate comprises:
a semiconductor layer; and
a gate structure formed on the semiconductor layer;
wherein the silicon nitride-containing capping layer covers a top surface and a vertical wall of the gate structure.

4. The method according to claim 3, wherein the silicon nitride-containing capping layer comprises:
a silicon oxide layer, covering the top surface and the vertical wall; and
a silicon nitride layer, covering the silicon oxide layer.

5. The method according to claim 1, wherein the sulfide-containing treatment agent comprises sulfuric acid (H₂SO₄), caro's acid (H₂SO₅) or a combination thereof.

6. The method according to claim 1, wherein the sulfide-containing treatment agent comprises H₂SO₄, hydrogen peroxide (H₂O₂) and water.

7. The method according to claim 6, wherein the sulfide-containing treatment agent has a sulfuric acid concentration substantially between 50 wt % and 95 wt %.

8. The method according to claim 7, wherein there is a functional relationship between a width of the remaining portion of the silicon nitride-containing capping layer and the sulfuric acid concentration.

9. The method according to claim 8, wherein the wet process is controlled by using an advanced process control (APC) system and/or an advanced equipment control (AEC) system taking account the function relationship.

10. The method according to claim 1, wherein the etch stop structure comprises a shallow trench isolation (STI).
